(19) United States
(12) Patent Application Publication
(10) Pub. No.: US 2026/0173797 A1
(43) Pub. Date: Jun. 18, 2026

(54) ETCHING SYSTEM AND ETCHING METHOD

(71) Applicant: Hitachi High-Tech Corporation, Minato-ku, Tokyo (JP)

(72) Inventors: Chisaki TAKUBO, Tokyo (JP); Makoto SATAKE, Tokyo (JP); Tadashi OKUMURA, Tokyo (JP)

(21) Appl. No.: 18/845,688

(22) PCT Filed: Jul. 10, 2023
(86) PCT No.: PCT/JP2023/025382

§ 371 Date: Sep. 10, 2024

(51) Int. Cl. H10P 72/00; H01J 37/32; H10P 74/00

(52) U.S. Cl. CPC H10P 72/0604; H01J 37/32935; H10P 72/0421; H10P 72/0602; H10P 74/23; H01J 2237/334

(57) ABSTRACT

An apparatus that calculates a first parameter having a high correlation with a temperature condition of an etching condition based on a measurement result of a pattern from a measuring apparatus, a second parameter having a low correlation with a temperature condition of the etching condition based on a measurement result of the pattern from the measuring apparatus, a temperature condition where the first parameter is within a permissible range based on the first parameter having been calculated, determines whether or not the second parameter having been calculated is within the permissible range, provides an etching condition where a condition other than the temperature condition is changed when the second parameter having been calculated is out of the permissible range, and provides an etching condition where a temperature condition is changed to the temperature condition having been calculated when the second parameter having been calculated is within the permissible range.

### TECHNICAL FIELD

The present invention relates to an etching system and an etching method improving uniformity of the shape within the wafer surface.

### BACKGROUND ART

Accompanying implementation of three-dimensional structure of the semiconductor device, the request for a manufacturing method of forming a complicated structure uniformly within a wafer surface has been increasing year by year. In manufacturing a semiconductor device, by executing etching by an etching apparatus after forming a pattern mask by an exposure apparatus, the aimed pattern is formed on the wafer front surface. Also, in order to confirm that the formed pattern has a desired size, it is common to execute measurement using a semiconductor inspection apparatus such as a CD-SEM (Critical Dimension Scanning Electron Microscope) and an OCD (Optical Critical Dimension).

As a prior art of etching, there is known an etching system improving uniformity within the wafer surface of a CD (Critical Dimension) value corresponding to the pattern width of a top view by executing etching controlling the temperature within the wafer surface by plural heating elements. For example, in Patent Literature 1, as an etching system and an etching method, there is described a technology for improving uniformity within the surface of the CD value by executing etching achieving the temperature profile of plural heating elements determined by the relation between the CD shift amount of each temperature measured beforehand and the temperature and the CD value before processing the wafer. Here, the CD shift amount expresses the change amount of the CD value before and after etching.

### CITATION LIST

### Patent Literature

Patent Literature 1: Japanese Unexamined Patent Application Publication No. 2013-77859

### SUMMARY OF INVENTION

### Technical Problem

According to the prior art described above, since consideration was insufficient with respect to the following point, a problem occurred. That is to say, according to the prior art described above, uniformity within the wafer surface of the CD value is improved by controlling the temperature of an electrode configured of plural heating elements. However, implementation of three-dimensional device structure has taken place in the semiconductor device of recent years, and there is required uniformity not only of one parameter of the CD value but also of plural parameters including the cross-sectional shape.

On the other hand, when uniformity of plural parameters is to be considered, it is easily thought of that the uniformity of the plural parameters can be improved by controlling the electrode temperature of each parameter similarly to a prior art. However, it is not to say in fact that there is the temperature sensitivity in all parameters. As shown in Patent Literature 1, the CD value has high temperature sensitivity, and uniformity of the CD value within the wafer surface can be improved by adjusting the temperature of each electrode configured of plural heating elements that set the wafer temperature. However, it was known that there was a parameter where variation by the temperature is small and the temperature sensitivity is low. With respect to this parameter, it was found out that improvement of uniformity within the surface was hard even when etching processing was executed only by controlling the temperature of the electrode calculated from the temperature sensitivity as the prior art, and that there was a risk that a desired shape could not be obtained.

As described above, according to the prior art, it was not considered to achieve the uniformity within the wafer surface of plural parameters including a parameter whose temperature sensitivity was low. The object of the present invention is to provide an etching system and an etching method improving yield of processing considering improvement of uniformity within a wafer surface of plural parameters including a parameter whose temperature sensitivity is low.

### Solution to Problem

An etching system that is an embodiment of the present invention includes an etching apparatus etching a wafer, a measuring apparatus measuring a pattern formed on a surface of the wafer etched by the etching apparatus, and a calculating apparatus providing the etching apparatus with an etching condition, and the calculating apparatus calculates a first parameter and a second parameter, the first parameter having a high correlation with a temperature condition out of the etching condition based on a measurement result of the pattern from the measuring apparatus, the second parameter having a low correlation with a temperature condition out of the etching condition based on a measurement result of the pattern from the measuring apparatus, calculates a temperature condition where the first parameter is within a permissible range based on the first parameter having been calculated, determines whether or not the second parameter having been calculated is within the permissible range, provides an etching condition where a condition other than the temperature condition is changed when the second parameter having been calculated is out of the permissible range, and provides an etching condition where a temperature condition is changed to the temperature condition having been calculated when the second parameter having been calculated is within the permissible range.

### Advantageous Effects of Invention

According to the present invention, yield of processing improves by restudying the condition other than temperature with respect to dispersion of the second parameter having low temperature sensitivity in addition to the distribution within the surface of the first parameter having temperature sensitivity using data measured by the measuring apparatus, repeating restudying until distribution of the first parameter and the second parameter falls within a permissible range, modifying the temperature distribution corresponding to an initial target CD value, and adjusting a heater so as to achieve the obtained temperature distribution to process the wafer.

### BRIEF DESCRIPTION OF DRAWINGS

FIG. 1 is a schematic view illustrating a device configuration of a semiconductor etching system related to an embodiment of the present invention.

FIG. 2 is a vertical cross-sectional view schematically illustrating a configuration of a wafer stage provided by an apparatus of the semiconductor etching system related to the embodiment.

FIGS. 3A and 3B are plan views schematically illustrating an example of the layout of a heater zone of an upper surface of a wafer stage related to the embodiment.

FIG. 4 is a flowchart illustrating a flow of the operation within a calculating apparatus related to the embodiment.

FIG. 5 is a drawing schematically illustrating a measurement position within the wafer surface.

FIG. 6 is a schematic drawing explaining the CD and the difference of left and right slopes in a cross section.

FIGS. 7A-7C are examples of a SEM image objecting a line pattern of a semiconductor device, a schematic cross-sectional view corresponding to it, and a secondary electronic signal waveform of a SEM.

FIG. 8 is an example of a secondary electronic signal waveform calculating a feature quantity that is a three-dimensional shape indicator, a primary differentiated waveform of it, and a three-dimensional shape corresponding to it.

FIGS. 9A and 9B are values of the CD which is the first parameter and the difference of left and right slopes which is the second parameter calculated from a SEM image.

FIGS. 10A and 10B are obtained by converting the CD which is the first parameter and the difference of left and right slopes which is the second parameter into a graph of temperature sensitivity of the temperature.

FIGS. 11A and 11B are drawings explaining a calculation method of the temperature of each electrode for changing a graph of temperature sensitivity to a parameter value that is uniform within the surface.

FIG. 12 is a graph explaining a state of low temperature sensitivity.

FIGS. 13A and 13B are drawings expressing reduction of dispersion of the CD value by temperature control and dispersion of the difference of left and right slopes.

FIG. 14 is a drawing expressing reduction of dispersion of the difference of left and right slopes by changing the gas kind.

### DESCRIPTION OF EMBODIMENTS

An embodiment of the present invention will be hereinafter explained referring to the drawings. Also, the present invention is not to be limited by this embodiment. Also, in description of the drawings, a same portion is expressed by marking a same reference sign. When there are plural configuration elements having a same or similar function, there is a case of explanation adding different subscripts to a same reference sign. Also, when it is not required to discriminate these plural configuration elements, there is a case of explanation omitting the subscript. There is a case that the position, size, shape, range, and the like of each configuration element illustrated in the drawing do not express an actual position, size, shape, range, and the like in order to facilitate understanding of the invention. Therefore, the present invention is not to be necessarily limited to the position, size, shape, range, and the like disclosed in the drawings.

### First Embodiment

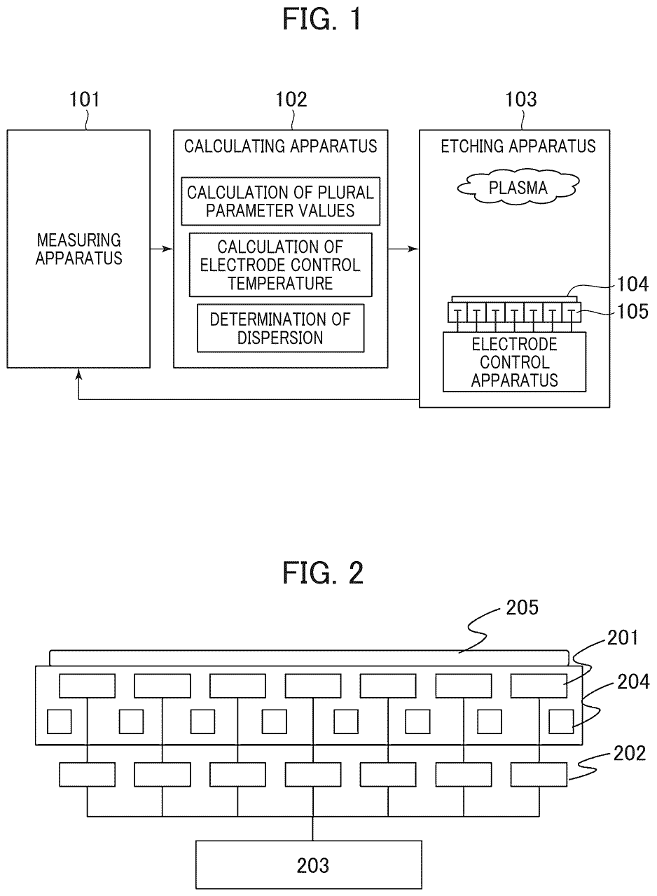

First, the embodiment of the present invention will be explained using FIG. 1. FIG. 1 is a schematic view illustrating a configuration of a semiconductor etching system related to the embodiment of the present invention. In the present drawing, a configuration of the whole semiconductor etching system is schematically illustrated, and there is illustrated an apparatus that is a processing apparatus for a semiconductor wafer such as an etching processing apparatus and is an apparatus processing the semiconductor wafer to achieve distribution of a prescribed physical quantity (the shape or dimension of a pattern for a circuit formed on a wafer surface for example) in the direction within the surface of the wafer.

The semiconductor etching system of the present embodiment includes an etching apparatus 103, a measuring apparatus 101, and a calculating apparatus 102, the etching apparatus 103 including a wafer stage 105 in a container of the etching apparatus 103, a wafer 104 being arranged in the wafer stage 105, the wafer stage 105 having a function of variably adjusting distribution of the temperature in the direction within the surface of the wafer 104, the measuring apparatus 101 being capable of measuring distribution of a prescribed physical quantity within the wafer surface, the calculating apparatus 102 including a calculator and a mechanism, the calculator executing calculation of plural parameter values including a CD value obtained from a result of measurement of a pattern formed on a surface of a wafer of plural positions having been set beforehand by the measuring apparatus 101 and calculation of the temperature of plural positions of the wafer or a stage supporting the wafer using the parameter value, the mechanism determining whether or not dispersion of the parameter is within a permissible range.

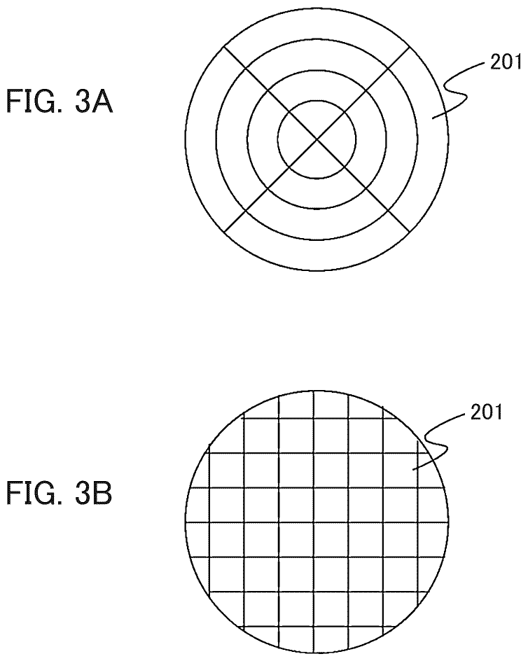

FIG. 2 is a cross-sectional view schematically illustrating a wafer stage and a configuration of temperature adjustment of the etching apparatus related to the embodiment. The wafer stage 105 includes plural heaters 201 and a coolant flow path 204 below a surface mounting a processing wafer 205, the heaters 201 executing heating, the coolant flow path 204 being for executing cooling. Temperature distribution in the direction within the surface of the wafer stage 105 is adjusted by adjustment of the heat generation amount of the plural heaters 201 and adjustment of the temperature of the coolant. The plural heaters 201 are disposed in each area of the wafer stage 105, and the area is split by a method for splitting into a concentric way as FIG. 3A, a method of splitting into a rectangular shape as (FIG. 3B and so on. This split area is called an electrode. The number of piece and the size of splitting is not limited to those exemplified. Also, 202 is a temperature adjustment instrument for the electrode of the heater, and adjusts the temperature of the upper surface of the stage mounting the wafer so as to become the wafer temperature calculated by the calculating apparatus 102 using a sensor value obtained from the plural temperature sensors arranged in the electrode of the heater although the plural temperature sensors are not illustrated. This adjustment is controlled by a heater control unit 203.

The coolant flow path 204 allows coolant to flow circulatingly between a coolant temperature controller connected through a pipe line not illustrated, and the temperature of the coolant is adjusted to a temperature range determined beforehand in the coolant temperature controller. Although the coolant flow path 204 is disposed below the heater 201 in the drawing, the coolant flow path 204 can be disposed above the heater 201. Also, when the wafer temperature can be adjusted to a desired value only by the heater 201, the coolant may not be used.

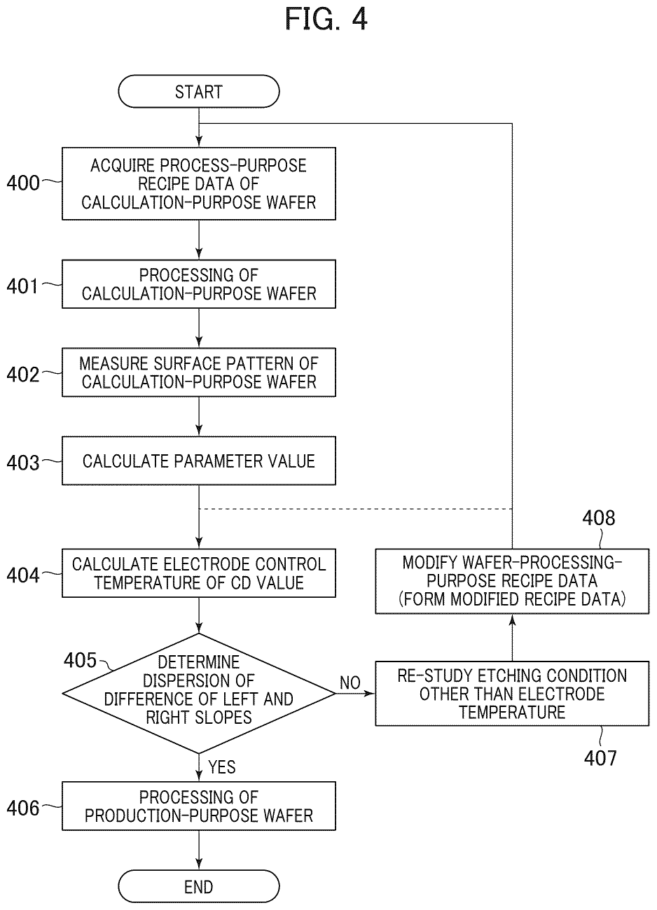

The calculating apparatus 102 is an apparatus for producing an etching condition enabling uniformity within the wafer surface of the CD value and the shape before etching a real production wafer, calculating a stage temperature for the purpose, and transferring the calculation result to the etching apparatus 103. FIG. 4 illustrates a flowchart of the process executed by the calculating apparatus. According to the present embodiment, first, etching process is executed using a calculation-purpose wafer. The calculation-purpose wafer is a wafer separate from a wafer for production of a semiconductor device (apparatus) (real production wafer) which is processed beforehand and where a parameter required for determining the condition of the process described above is detected in order to acquire a condition of a process with which distribution of the CD value, shape, and dimension in the direction within the surface of the membrane structure on the wafer after the process can be made one within a desired range before subjecting the real production wafer to an etching process, and is a wafer where a membrane structure and a pattern same to or similar to a degree of being regarded to be same to the membrane structure including plural membrane layers including at least a membrane of the processing object and the pattern disposed on the upper surface of the real production wafer are disposed on the upper surface beforehand.

In the first step 400, data expressing operation of the etching apparatus 103 (process-purpose recipe data) including the condition of the process such as the flow rate of the processing gas, the pressure within the processing chamber, the temperature of the wafer during the process and distribution thereof when the etching apparatus 103 illustrated in FIG. 1 processes the calculation-purpose wafer namely a so-called process-purpose recipe are acquired by the calculating apparatus 102 through a communication means and are stored in a storage apparatus in the inside of the calculating apparatus 102. Next, in the step 401, an etching process is executed using the calculation-purpose wafer based on the process-purpose recipe data having been acquired. According to the present embodiment, the process is executed based on the condition of different temperatures with respect to each of the plural sheets of the calculation-purpose wafer.

As described also in Patent Literature 1, it is known that the CD value has temperature sensitivity and becomes different values according to the temperature. From this fact, in the step 401, a process for calculating temperature sensitivity of a desired pattern is executed changing the temperature with respect to plural calculation-purpose wafers. According to the present embodiment, etching process for each of two sheets of the calculation-purpose wafer is executed with a condition of being made 10° C. and 50° C. with respect to the direction within the surface as the wafer temperature during the process, particularly with the condition where the temperature detected at each of plural positions of the wafer or the wafer stage during the process is made within a prescribed permissible range, and the CD value and distribution thereof are detected from these calculation-purpose wafers.

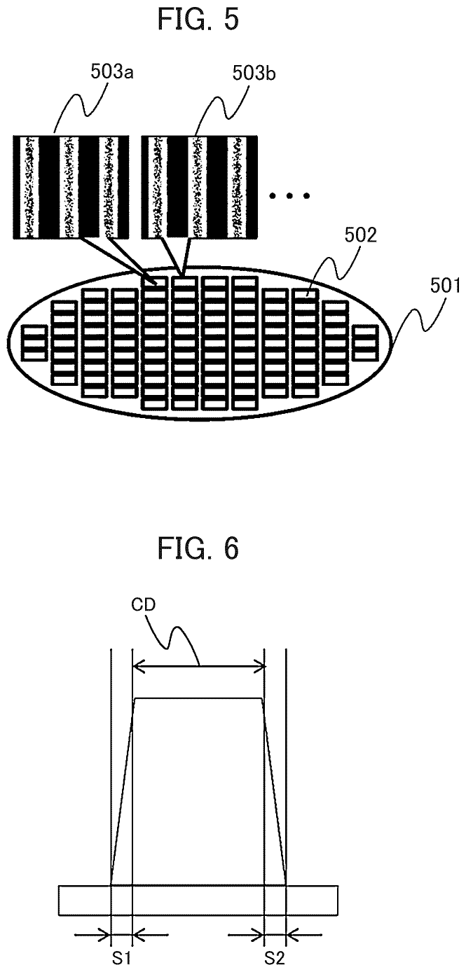

Next, in the step 402, plural calculation-purpose wafers having been processed are measured. According to the present embodiment, the CD value of the pattern is measured using a CD-SEM apparatus conventionally used in common. The reason is that measurement by the CD-SEM apparatus is non-destructive and with a high speed. According to the present embodiment, with respect to predetermined plural positions of each calculation-purpose wafer upper surface 501, an image of a desired pattern of the position in question is captured by the CD-SEM apparatus from top view. At this time, distribution in the direction within the surface of the measured value obtained with respect to the plural positions of the calculation-purpose wafer upper surface 501 as illustrated in FIG. 5 can be calculated. A shape after working formed in each position in the inside of each of plural pieces determined beforehand out of dies 502 where each device pattern of the calculation-purpose wafer upper surface 501 corresponding to each semiconductor device (chip) cut out eventually from the wafer is measured, and SEM images 503a, 503b . . . are captured.

The CD-SEM image is one obtained by detecting secondary electrons excited from atoms by scattering of incident electrons within a sample in the SEM and displaying the secondary electrons by a contrasting density (brightness) for each pixel of the image. The CD-SEM image expresses intensity of the secondary electron signal having been detected, and includes information of a three-dimensional shape of the pattern. According to the present embodiment, there are captured a SEM image of plural positions within the surface of the calculation-purpose wafer etched with a condition where the water temperature is made 10° C., and plural images of the calculation-purpose wafer etched with a condition of 50° C. With respect to the pattern at a determined position of the inside of a region of each of 110 pieces of dies 502 formed on each of the calculation-purpose wafer upper surfaces 501, an image was captured respectively.

Also, the positions where the temperature of the wafer or the wafer stage is detected in the present embodiment are disposed below a region of each heater 201 where the output or the heat generation amount is adjusted so that the temperature outside the window is made a desired value by the electrode control apparatus and within the projection plane as viewed from the top thereof, and the number of piece of these positions is made equal to or greater than the number of piece of the heater 201. Even when the wafer temperature is made a predetermined value with respect to the direction within the surface as the steps 400, 401, the output and the heat generation amount of each heater 201 are adjusted so that dispersion of each value becomes within a desired range with respect to a set of the value of the temperature detected at plural positions. In an example of the heater 201 having a rectangular region illustrated in FIG. 3B, the dimension of each heater is made smaller than the dimension of each die 502, and each heater 201 is adjusted in this example based on a temperature detected at positions of a number of piece greater than that of the die 502.

Next, in the step 403, a shape parameter expressing a three-dimensional shape is calculated from the CD-SEM image having been captured. A parameter with high temperature sensitivity namely a CD value for example is calculated as the first parameter, and a parameter having low temperature sensitivity namely having low correlation with the wafer temperature and high correlation with a processing condition other than temperature, for example, a difference of left and right slopes of a cross section which has been capable of being confirmed experimentally to have low temperature sensitivity is calculated as the second parameter. Further, according to the present invention, a parameter having low correlation with temperature is to include also a parameter having no correlation with temperature.

As illustrated in FIG. 6, the CD value expresses the width of the cross section, and the difference of left and right slopes is the difference of left and right slopes of the cross section of the pattern |S1-S2|. In forming a pattern by SADP (Self-Aligned Double Patterning), uniformity within the wafer surface of this parameter becomes important.

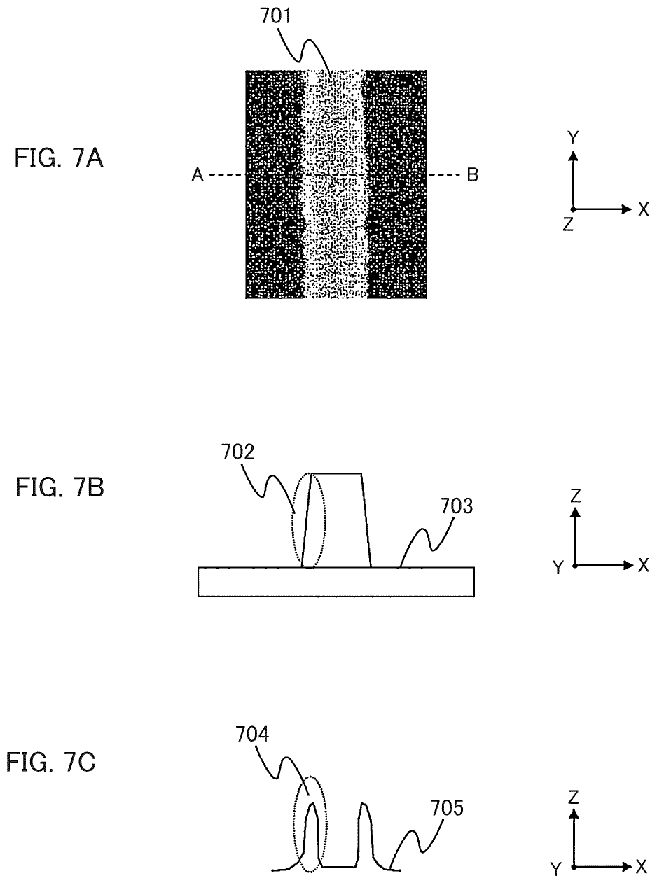

Here, explanation will be made on the SEM image and a method for calculating a parameter from the image. FIGS. 7A-7C illustrate an example of a SEM image objecting a line pattern of a semiconductor device. FIG. 7A is a two-dimensional SEM image which is a top view image of a line pattern. In this SEM image, there is one piece of the line pattern extending in Y direction within X-Y plane illustrated corresponding to within the wafer surface. In this image, every pixel has a contrasting density (brightness).

FIG. 7B is an example of the cross-sectional shape of the pattern at the position illustrated in A-B of FIG. 7A, and corresponds to X-Z cross section. FIG. 7C (is an example of the secondary electron signal waveform of the SEM corresponding to the contrasting density of an image 701 of FIG. 7A and the cross-sectional shape of FIG. 7B. This waveform is called also a line profile. This signal waveform has high sensitivity to the inclination angle of the cross section of the pattern that is the measurement object, and the signal quantity at the side wall portion of the pattern becomes greater than the signal quantity of the flat portion of the pattern. A slope 702 portion of the cross-sectional shape of FIG. 7B (generally corresponds to 704 of the signal waveform of FIG. 7C, and a flat portion 703 generally corresponds to 705. Thus, it is known that the signal waveform changes according to the cross-sectional shape of the pattern.

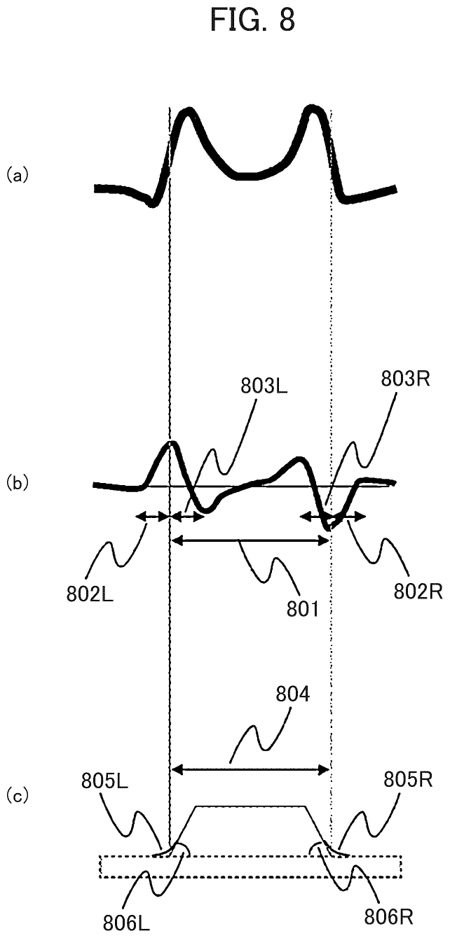

On the other hand, from this signal waveform, one called a feature quantity for presuming the cross-sectional shape can be calculated. The feature quantity expresses a value of a peak, width, and the like obtained from the waveform of each of a secondary electron signal waveform and a primary differentiated waveform and a secondary differentiated waveform thereof, and is a shape indicator expressing the feature of the shape of the pattern. FIG. 8 illustrates an example of the feature quantity. (a) illustrates a secondary electron signal waveform, (b) illustrates a primary differentiated waveform thereof, and (c) illustrates a cross-sectional shape of a pattern. The value of the width of the waveform illustrated by an arrow is called a feature quantity, and the shape such as the pattern width (801, 804), the footing (802, 805), and the inclination angle of the side surface (803, 806) which are the measurement objects is captured from the relation of these plural feature quantities.

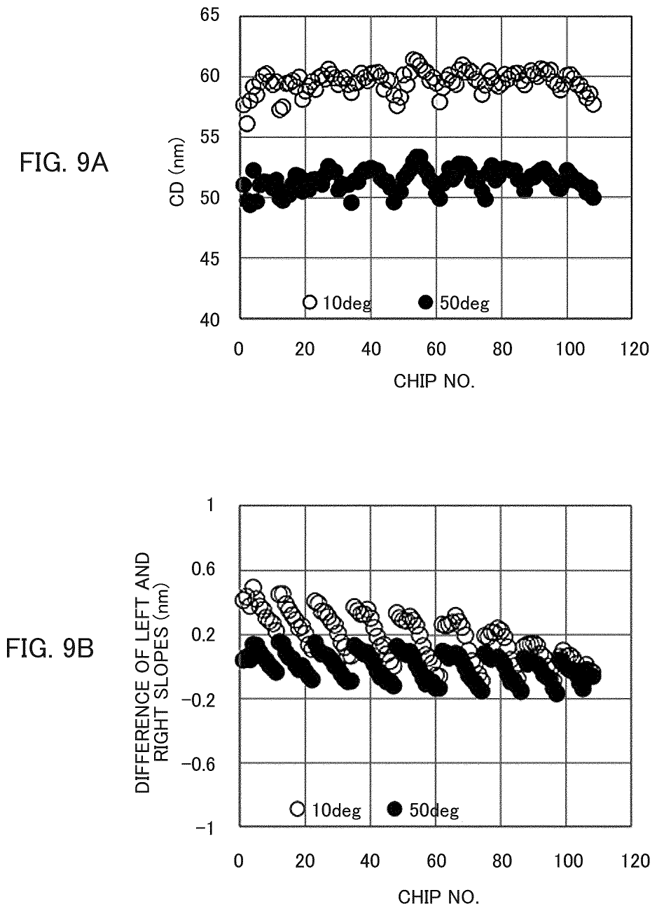

According to the present embodiment, FIGS. 9A and 9B illustrate the CD value that is the first parameter and the value of the difference of left and right slopes that is the second parameter obtained from the SEM image by this calculation method. FIG. 9A is the CD value of the first parameter, and FIG. 9B is the value of the difference of left and right slopes of the second parameter. The white circle corresponds to the temperature condition in processing the calculation-purpose wafer is 10° C., the black circle corresponds to the temperature condition in processing the wafer is 50° C., and the horizontal axis of the graph expresses 110 positions measured in each wafer having been etched.

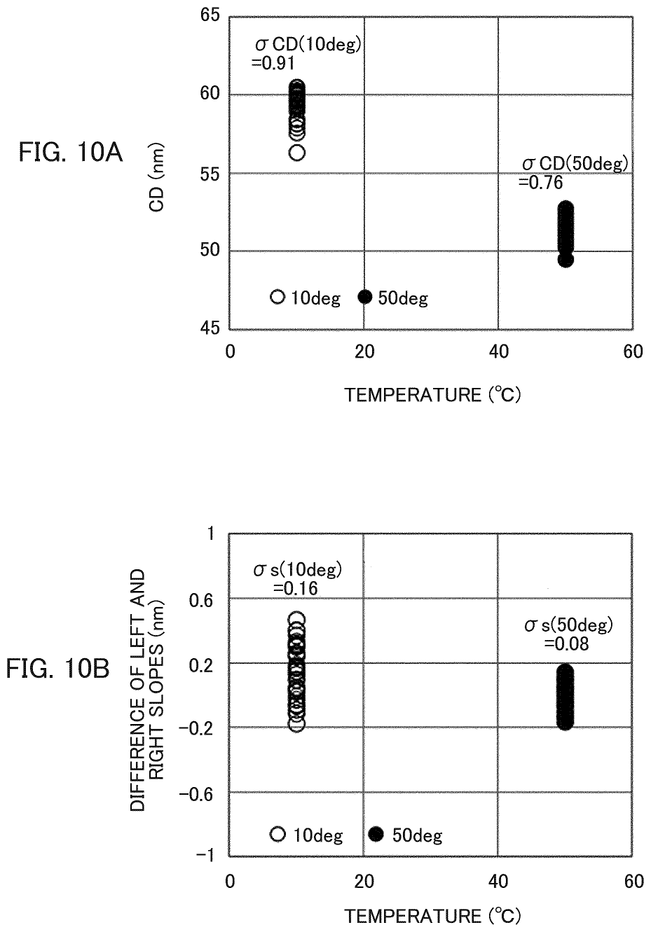

Next, they are converted into a graph whose horizontal axis represents the temperature sensitivity of the temperature, and the initial dispersion oi of each is calculated (FIGS. 10A and 10B). According to the present embodiment, there is used a value of the first parameter and the second parameter after coordinate transformation from the CD-SEM measurement coordinate to the electrode coordinate of the etching apparatus. The initial dispersion (standard deviation) of the 10° C. wafer of the CD value of the first parameter was σCD (10 deg)=0.91, dispersion of the 50° C. wafer was σCD (50 deg)=0.76, and dispersion of the difference of left and right slopes of the second parameter was σs (10 deg)=0.16 for the 10° C. wafer and was σs (50 deg)=0.08 for the 50° C. wafer.

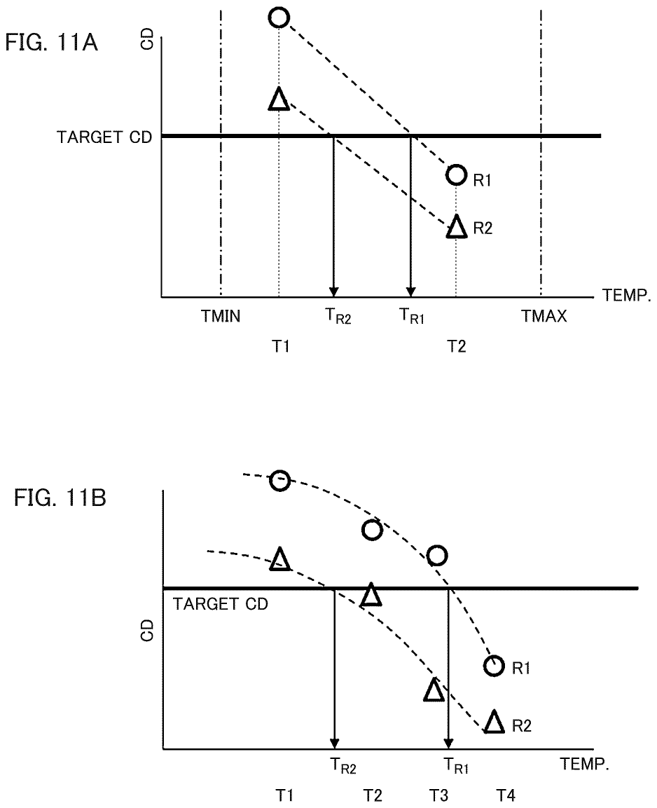

Next, in the step 404 of the flow of FIG. 4, the electrode control temperature of the first parameter (CD value) is calculated. A method for calculating the temperature of each electrode for achieving a parameter value that is uniform within the surface from the graph of the temperature sensitivity will be explained using FIGS. 11A and 11B. For the sake of explanation, in FIG. 11A, the CD value obtained by measuring the calculation-purpose wafer having been etched at the temperature T1 and T2 by the CD-SEM is plotted only for the electrode number R1 (°) and R2 (Δ), and the broken line is the primary linear approximating line of each electrode. From this primary linear approximating line, the electrode temperature of each for achieving the target CD value illustrated in the graph is calculated. That is to say, as illustrated by the arrow, temperature T_{R1} of the electrode R1 is obtained from the intersection point of the primary linear approximating line of the electrode R1 and the target, and temperature T_{R2} of the electrode R2 is obtained from the intersection point of the primary linear approximating line of the electrode R2 and the target.

Also, when the calculation-purpose wafer is worked at plural temperatures of T3, T4 . . . other than T1 and T2 and there exist plural data as illustrated in FIG. 11B, the data are approximated not by a primary linear approximating line but by a secondary curve approximating line as the broken line illustrated in FIG. 11B.

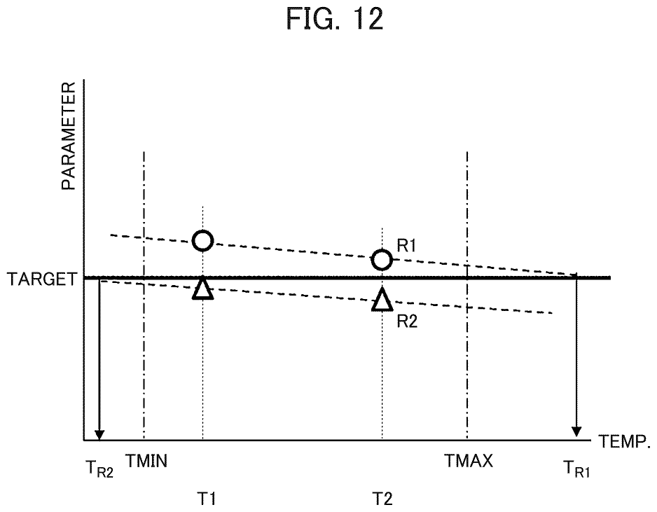

Here a parameter having low temperature sensitivity will be explained. The electrode is a part of the etching apparatus, and there is a range in the controllable temperature. For example, when the lowest temperature is made Tmin and the highest temperature is made Tmax, the calculation-purpose wafer working temperature T1 and T2 are normally within the range of Tmin to Tmax. Further, in FIGS. 11A and 11B also, the temperature T_{R1}, T_{R2} having been calculated also is within the range of Tmin to Tmax. On the other hand, when the inclination by the temperature is gentle as illustrated in FIG. 12, the temperature T_{R1} and T_{R2}obtained from the intersection of the approximating line of each electrode and the target value become a temperature out of the range of Tmin to Tmax. In this case, the electrode temperature cannot be achieved. Also, an event that the inclination is gentle as described above results that, even when the temperature is changed between Tmin and Tmax, change of the parameter value is small and the temperature sensitivity is low.

The step 405 that is the next flow of FIG. 4 is a step for determining whether or not dispersion of the second parameter (difference of left and right slopes) having low temperature sensitivity is within a prescribed permissible range. When dispersion is within a prescribed value (Yes), it is determined that dispersion of both parameters of the first parameter (CD value) and the second parameter calculated in the step 404 with respect to the shape after working by the etching process based on the initial process-purpose recipe data including the temperature condition is a value within a prescribed permissible range required for a semiconductor device or manufacturing thereof, and the process shifts to a step for processing the real production wafer for manufacturing the semiconductor device which is the next step 406.

On the other hand, when dispersion of the second parameter is out of the prescribed value (No), even when dispersion of the first parameter (CD value) is within a permissible range by temperature control in accordance with the initial process-purpose recipe data, there is a risk that a problem occurs in the semiconductor device or manufacturing thereof in terms of the second parameter (difference of left and right slopes). In this case, the process shifts to the steps of the step 407 and onward, and the data are modified to the process-purpose recipe data where a condition having a high correlation with the second parameter out of the conditions of processing of the wafer is changed so that dispersion of the second parameter becomes a value within a permissible range

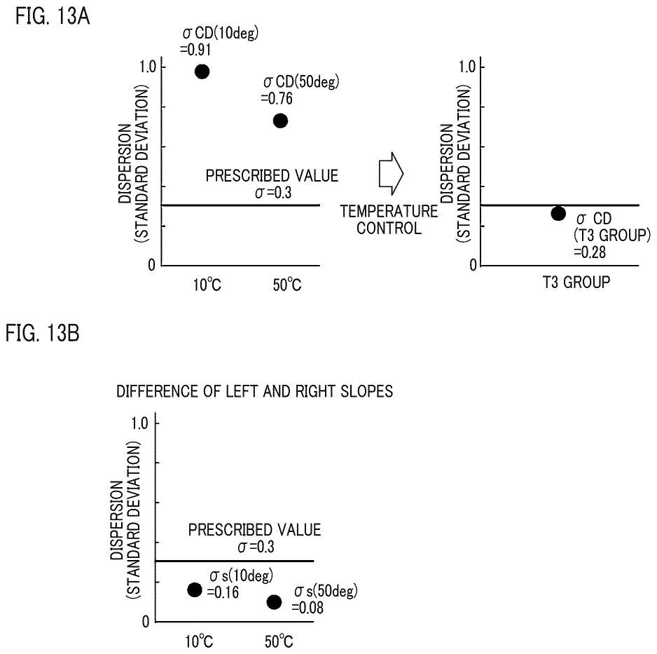

In concrete terms, when the data of FIGS. 10A and 10B are used, the initial dispersion σCD (10 deg) and σCD (50 deg) of the CD value obtained in processing of the calculation-purpose wafer in each of the temperature conditions 10° C. and 50° C. included in the process-purpose recipe data as an initial value are calculated, and these values are compared to the upper limit value of the permissible range of dispersion of the CD value. When it is determined that the value of dispersion is out of the permissible range where the upper limit value is made the threshold, in order to make dispersion of the CD value a value within the permissible range, there are calculated, by the calculating apparatus, the value of the temperature and distribution thereof which are to be set at plural positions described above where the temperature is detected. With a set of the set value of the temperature at plural positions described above during processing as a condition of such processing being made a temperature group, dispersion σCD (T3 group) of the result of processing of the calculation-purpose wafer adjusting the heater 201 so as to achieve these temperatures with the condition of processing using the temperature group temperature T3 group modified so that dispersion of the CD value improves becomes one illustrated in FIG. 13A.

On the other hand, FIG. 13B illustrates the result of plotting dispersion of the difference of left and right slopes σS (10 deg) and σS (50 deg), and when the prescribed value of dispersion is made σ=0.3, it is known that both of dispersion of the difference of left and right slopes are within the prescribed value (Yes). In the case of these data, since both of dispersion of the CD value and dispersion of the difference of left and right slopes after temperature control can be suppressed to within the prescribed value, it is known that the process can proceed to processing of the production-purpose wafer which is based on the process-purpose recipe data where the temperature group T3 is made the condition of processing.

On the other hand, when dispersion of the second parameter is out of the prescribed value (No), even when dispersion of the first parameter (CD value) is made within the prescribed value by temperature control, the second parameter (difference of left and right slopes) cannot be made within the prescribed value, and therefore it comes that dispersion of both parameters cannot be made within the specification. In this case, according to the present embodiment, in order to reduce dispersion of the difference of left and right slopes, the condition of the etching process other than the temperature is re-studied, and the condition is set again. This step becomes the step 407 of FIG. 4.

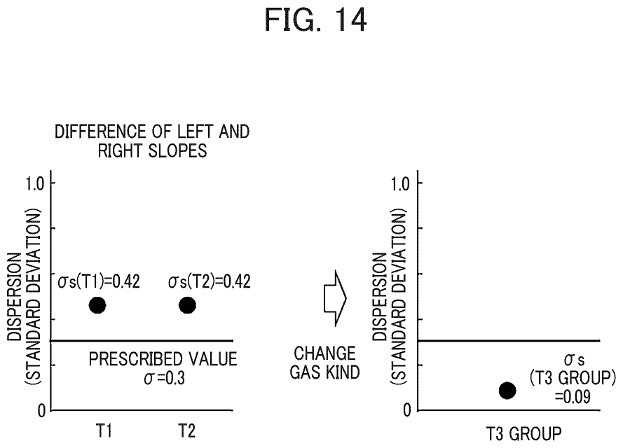

In the case of another experiment example illustrated in FIG. 14, dispersion of the difference of left and right slopes after working of the calculation-purpose wafer processed using an optional temperature group T2, T3 as the condition of processing was equal to or greater than the prescribed value, and dispersion could not be reduced even when the temperature was changed. In the case of this example, the condition of processing is newly set again assuming that the kind of the gas is changed and the condition of the temperature is changed to the temperature group T3 in the step 407, and modified process-purpose recipe data are formed in the step 408. Thereafter, the process returns to the step 400, the process-purpose recipe data after modification are transmitted to the etching apparatus, and the steps 401 to 405 are executed again. The first and second parameters are detected from the pattern data after working obtained by execution of these steps of the second time, and these values and dispersions are calculated.

As illustrated in FIG. 14, as a result, not only the CD value but also dispersion of the difference of left and right slopes could be reduced to 0.09 that was smaller than the prescribed value 0. 3. Since temperature sensitivity of the CD value also changes every time the etching condition is changed in the step 407, it is required to re-start from the step 401 every time to re-calculate the electrode control temperature of the CD value.

Also, if dispersion of the difference of left and right slopes cannot be made within the prescribed value in the step 405 when the etching condition is changed once and the steps 401 to 405 are executed, the step 407 is executed again and the flow is repeated. Thus, the steps 400 to 405 or the loupe of the steps 407, 408 is repeated until dispersion becomes within the prescribed value in determination of the step 405. Eventually, in processing of the production-purpose wafer of the step 406, processing comes to be executed using the process-purpose recipe where the processing condition based on the first parameter is modified based on determination using the second parameter.

Although the CD-SEM was used in order to obtain information of the three-dimensional shape in the measuring apparatus of the present embodiment, such method is also possible that the cross-sectional shape of the pattern is directly observed and measured after producing a cross section by breakage, FIB, and the like. Further, although the step 404 is executed after the step 403 for calculating the parameter including the first parameter and the second parameter for the calculation-purpose wafer and before the step 405 which is a step for determination using the second parameter, when determination in the step 405 is out of the prescribed value (No), the step 404 may be executed before modification of the process-purpose recipe data of the time before calculating the parameter again in the step of the step 400 and onward.

Further, although the difference of left and right slopes was selected for the second parameter having low temperature sensitivity in the present embodiment, since it is known that the sub-trench and mask erosion have low temperature sensitivity experimentally and uniformity within the surface can be improved by re-studying not the temperature but the wafer bias, similar effects can be secured even when they are selected as the second parameter.

Further, with respect also to a shape parameter whose temperature sensitivity has not been known, temperature sensitivity of the parameter can be confirmed as illustrated in FIGS. 11A and 11B and FIG. 12 of the present embodiment. In the case, by calculating temperature sensitivity of a feature quantity calculated from the SEM image, temperature sensitivity of a three-dimensional shape parameter having strong correlation with the feature quantity is known.

Since plural feature quantities corresponding to a three-dimensional shape parameter is calculated from the SEM image, it is also possible to confirm temperature sensitivity of each feature quantity and to select a feature quantity having high temperature sensitivity as the first parameter and a feature quantity having low temperature sensitivity as the second parameter.

Also, when a parameter that is not the difference of left and right slopes required to be detected by the CD-SEM after processing of the calculation-purpose wafer of the second time using the process-purpose recipe data after modification as the second parameter and not requires wafer processing of the second time is used, as a step to which the process returns from the step 408, not the step 400 but the step 403 or 404 may be selected out of the flowchart illustrated in FIG. 4. In this case, it is necessary that the value of the parameter as a result of processing using a condition of processing of the modified process-purpose recipe data can be detected or calculated with a predetermined accuracy without using an actual etching process, namely numerical value simulation is used for example.

Since the first and second parameters of the present embodiment were of a same dimension of the width (nm), they could be comparingly studied as they were, however, plural feature quantities corresponding to a three-dimensional shape parameter are of a dimension different from each other. In this case, in order that comparison can be effected by a same dimension, it is required to execute a standardizing process of data using the data of a reference die. Although the CD value and the three-dimensional shape were assumed to be a physical quantity, an electrical property also will be applicable. In that case, as a measuring apparatus, an electrical property evaluation apparatus is used instead of the CD-SEM.

### List of Reference Signs

101: measuring apparatus,
102: calculating apparatus,
103: etching apparatus,
104: wafer,
105: wafer stage,
201: heater,
202: temperature adjustment instrument,
203: heater control unit,
204: coolant flow path,
205: processing wafer,
501: calculation-purpose wafer upper surface,
502: die,
503: SEM image.

1. An etching system comprising:
an etching apparatus etching a wafer; a measuring apparatus measuring a pattern formed on a surface of the wafer etched by the etching apparatus; and a calculating apparatus providing the etching apparatus with an etching condition, wherein
the calculating apparatus calculates a first parameter and a second parameter, the first parameter having a high correlation with a temperature condition out of the etching condition based on a measurement result of the pattern from the measuring apparatus, the second parameter having a low correlation with a temperature condition out of the etching condition based on a measurement result of the pattern from the measuring apparatus, calculates a temperature condition where the first parameter is within a permissible range based on the first parameter having been calculated, determines whether or not the second parameter having been calculated is within the permissible range,
provides an etching condition where a condition other than the temperature condition is changed when the second parameter having been calculated is out of the permissible range, and provides an etching condition where a temperature condition is changed to the temperature condition having been calculated when the second parameter having been calculated is within the permissible range.

2. The etching system according to claim 1, wherein
the first parameter is a CD value of the pattern, and the second parameter is a difference between widths of right and left slopes of a cross section of the pattern.

3. The etching system according to claim 2, wherein
the measuring apparatus is a CD-SEM measuring apparatus, and captures a SEM image from a top view of the pattern.

4. The etching system according to claim 3, wherein
a CD value of the pattern and a difference between widths of right and left slopes of the cross section are calculated from the SEM image.

5. The etching system according to claim 4, wherein,
when the difference between widths of right and left slopes of a cross section of the pattern having been calculated is out of a permissible range, the etching apparatus is provided with an etching condition where gas is changed.

6. An etching method using an etching apparatus etching a wafer, a measuring apparatus measuring a pattern formed on a surface of the wafer etched by the etching apparatus, and a calculating apparatus providing the etching apparatus with an etching condition,
the etching method comprising:
a first step of etching a wafer according to the etching condition having been provided;
a second step of measuring a pattern formed on a surface of the wafer having been etched in the first step;
a third step of calculating a first parameter and a second parameter, the first parameter having a high correlation with a temperature condition out of the etching condition based on a measurement result of the second step, the second parameter having a low correlation with a temperature condition out of the etching condition based on a measurement result of the second step;
a fourth step of calculating a temperature condition where the first parameter is within a permissible range based on the first parameter having been calculated in the third step;
a fifth step of determining whether or not the second parameter having been calculated in the third step is within a permissible range;
a sixth step of providing the etching apparatus with an etching condition where a condition other than a temperature condition is changed when determination of the fifth step is out of the permissible range; and
a seventh step of providing the etching apparatus with an etching condition changed to the temperature condition having been calculated in the fourth step when determination of the fifth step is within the permissible range, wherein,
when determination of the fifth step becomes out of the permissible range, the first to the sixth steps are repeated until determination of the fifth step becomes within the permissible range.

7. The etching method according to claim 6, wherein
the first parameter is a CD value of the pattern, and the second parameter is a difference between widths of right and left slopes of a cross section of the pattern.

8. The etching method according to claim 7, wherein
the measuring apparatus is a CD-SEM measuring apparatus, and captures a SEM image from a top view of the pattern in the second step.

9. The etching method according to claim 8, wherein
a CD value of the pattern and a difference between widths of right and left slopes of a cross section are calculated from the SEM image in the third step.

10. The etching method according to claim 9, wherein,
In the sixth step, the etching apparatus is provided with an etching condition where gas is changed in the sixth step.
